(19) United States
(12) Patent Application Publication
(10) Pub. No.: US 2012/0319787 A1
(43) Pub. Date: Dec. 20, 2012

(54) VOLTAGE CONTROLLED OSCILLATOR HAVING A RESONATOR CIRCUIT WITH A PHASE NOISE FILTER

(76) Inventors: VISHAL P. TRIVEDI, Chandler, AZ (US); KUN-HIN TO, Gilbert, AZ (US)

(21) Appl. No.: 13/163,036

(22) Filed: Jun. 17, 2011

(51) Int. Cl. H03B 5/12

(52) U.S. Cl. 331/117 FE

(57) ABSTRACT

An oscillator circuit is provided for generating an oscillating signal. The oscillator circuit includes a transistor circuit, a resonator circuit, and first and second transmission line open stubs. The transistor circuit is coupled to a first node and a second node of the oscillator circuit. The transistor circuit is for facilitating oscillation of the oscillating signal. The resonator circuit is coupled to the first node and the second node, and includes an inductance and a capacitance. The first and second transmission line open stubs are coupled to the first and second nodes, respectively. The first and second transmission line open stubs have a length substantially equal to a quarter wavelength of a second harmonic of the oscillating signal, and are for removing the second harmonic from the oscillating signal. In another embodiment, first and second half wave AC shorted stubs are used to remove the second harmonic from the oscillating signal.

### BACKGROUND

1. Field

This disclosure relates generally to voltage controlled oscillators, and more specifically, to a voltage controlled oscillator (VCO) having a resonator circuit with a phase noise filter.

2. Related Art

Voltage controlled oscillators are commonly used to produce an oscillating signal of a desired frequency in response to an input voltage. An inductor-capacitor (LC) tank circuit may used by a VCO to generate the oscillating signal. One or more variable capacitors (varactors) may be included in the LC tank circuit to vary a frequency of the oscillations. It is desirable to minimize phase noise in a VCO. There can be many sources of phase noise. For example, metal oxide semiconductor field effect transistors (MOSFETs) have higher low frequency or 1/f noise than a bipolar junction transistor (BJT) or a heterojunction bipolar transistor (HBT). The varactors can contribute to the total phase noise. Also, large-signal operation of the VCO in combination with MOSFET non-linear characteristics cause mixing and up-conversion that increase phase noise. In addition, the phase noise is a function of the bias voltage and drain current. It is desirable to reduce total noise and in particular, phase noise in a VCO.

Therefore, what is needed is a VCO that solves the above problems.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in schematic diagram form, a VCO circuit in accordance with an embodiment.

FIG. 2 illustrates, in schematic diagram form, a VCO circuit in accordance with another embodiment.

FIG. 3 illustrates, in block diagram form, a transmitter that can be implemented using the VCO circuits of FIG. 1 or FIG. 2.

### DETAILED DESCRIPTION

Generally, there is provided, a VCO circuit having a second harmonic filter to reduce phase noise. In one embodiment, the VCO circuit includes a quarterwave (λ/4) second harmonic transmission line open stub connected to output terminals of the VCO circuit. The second harmonic open stub presents a short, or low impedance, thus filtering out the second harmonic to reduce the phase noise. In another embodiment, the VCO circuit includes a halfwave (λ/2) transmission line stub coupled in series with a large capacitor to ground. The second harmonic is thus shorted, or filtered, with only minimal impact on tuning range of the VCO circuit. The transmission line stubs function as impedance transformers at the fundamental frequency and above.

In one aspect, there is provided, an oscillator circuit for generating an oscillating signal, the oscillator circuit comprising: a transistor circuit coupled to a first node and a second node of the oscillator circuit, the transistor circuit for facilitating oscillation of the oscillating signal; a resonator circuit coupled to the first node and the second node, the resonator circuit comprising an inductance and a capacitance; a first transmission line open stub having a first length substantially equal to a quarter wavelength of a second harmonic of the oscillating signal, the first transmission line open stub coupled to the first node; and a second transmission line open stub having a second length substantially equal to the quarter wavelength of the second harmonic of the oscillating signal, the second transmission line coupled to the second node, wherein the first and second transmission line open stubs are for removing a second harmonic from the oscillating signal. The transistor circuit may comprise: a first transistor having a first current electrode coupled to the first node, a second current electrode coupled to a first power supply voltage terminal, and a control electrode coupled to the second node; and a second transistor having a first current electrode coupled to the second node and to the control electrode of the first transistor, a second current electrode coupled to the first power supply voltage terminal, and a control electrode coupled to the first node. The inductance and the capacitance may further comprise: a first inductive element having a first terminal coupled to a second power supply voltage terminal, and a second terminal coupled to the first node; a second inductive element having a first terminal coupled to a second power supply voltage terminal, and a second terminal coupled to the second node; a first capacitive element having a first electrode coupled to the first node, and a second electrode for receiving a tuning voltage; and a second capacitive element having a first electrode coupled to the second node, and a second electrode coupled to the second electrode of the first capacitive element for receiving the tuning voltage. The first power supply voltage terminal may be coupled to ground and the second power supply voltage terminal may be coupled to receive a positive power supply voltage. The first and second inductive elements may each comprise transmission line segments. The first capacitive element and the second capacitive element may each comprise a varactor. The varactor may be characterized as being a metal-oxide semiconductor (MOS) varactor. The transistor circuit may comprise a pair of cross-coupled N-channel transistors. The oscillator circuit may be characterized as being a voltage controlled oscillator. The voltage controlled oscillator may be part of a radar frequency transmitter.

In another aspect, there is provided, an oscillator circuit for providing an oscillating signal, the oscillator circuit comprising: a transistor circuit coupled to a first node and a second node of the oscillator circuit; a resonator circuit coupled to the first node and the second node; a first half wave AC (alternating current) shorted stub coupled to the first node; and a second half wave AC shorted stub coupled to the second node, wherein the first and second half wave AC shorted stubs each comprise a transmission line in series with a capacitive element, wherein the transmission line has a length substantially equal to a half wavelength of a second harmonic of the oscillating signal, wherein the capacitive element is sized to provide a shorted input impedance at a fundamental frequency and above, and wherein the first and second half wave AC shorted stubs are for removing a second harmonic from the oscillating signal. The transistor circuit may comprise: a first transistor having a first current electrode coupled to the first node, a second current electrode coupled to a first power supply voltage terminal, and a control electrode coupled to the second node; and a second transistor having a first current electrode coupled to the second node and to the control electrode of the first transistor, a second current electrode coupled to the first power supply voltage terminal, and a control electrode coupled to the first node. The resonator circuit may further comprise: a first inductive element having a first terminal coupled to a second power supply voltage terminal, and a second terminal coupled to the first node; a second inductive element having a first terminal coupled to a second power supply voltage terminal, and a second terminal coupled to the second node; a first capacitive element having a first electrode coupled to the first node, and a second electrode for receiving a tuning voltage; and a second capacitive element having a first electrode coupled to the second node, and a second electrode coupled to the second electrode of the first capacitive element for receiving the tuning voltage. The first power supply voltage terminal may be coupled to ground and the second power supply voltage terminal may be coupled to receive a positive power supply voltage. The first and second inductive elements may each comprise transmission line segments. The first capacitive element and the second capacitive element may each comprise a varactor. The transistor circuit may comprise a pair of cross-coupled N-channel transistors. The oscillator circuit may be characterized as being a voltage controlled oscillator. The voltage controlled oscillator may be part of a radar frequency transmitter.

The semiconductor substrate described herein can be any semiconductor material or combinations of materials, such as gallium arsenide, silicon germanium, silicon-on-insulator (SOI), silicon, monocrystalline silicon, the like, and combinations of the above.

As used herein the term metal-oxide-semiconductor and the abbreviation MOS are to be interpreted broadly, in particular, it should be understood that they are not limited merely to structures that use “metal” and “oxide” but may employ any type of conductor including “metal” and any type of dielectric including “oxide”. The term field effect transistor is abbreviated as “FET”.

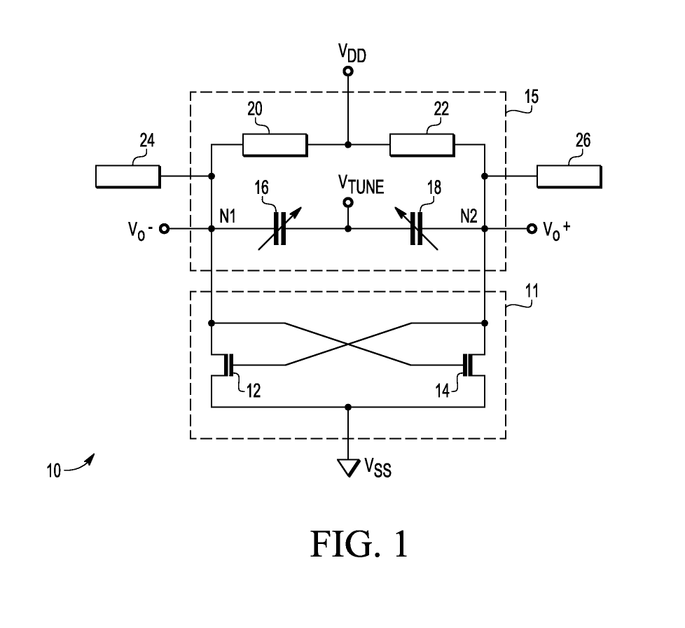

FIG. 1 illustrates, in schematic diagram form, VCO circuit 10 in accordance with an embodiment. VCO circuit 10 includes transistor circuit 11 and resonator circuit 15. Transistor circuit 11 and resonator circuit 15 work together to generate differential oscillating signals labeled “Vₒ₋” and “Vₒ₊” at nodes N1 and N2, respectively. The differential oscillating signals Vₒ₋ and Vₒ₊ are generally 180 degrees out of phase with each other. Transistor circuit 11 includes N-channel transistors 12 and 14. Resonator circuit 15 is an LC tank circuit and includes variable capacitors (varactors) 16 and 18 and inductors 20 and 22. Transmission line stubs 24 and 26 have a length substantially equal to, or comparable to, a quarter wavelength (λ/4) of a second harmonic of the oscillating signals Vₒ₋ and Vₒ₊. Transmission line stubs 24 and 26 have one end terminated in an open while having the other end connected to a corresponding one of nodes N1 and N2 as illustrated in FIG. 1.

In transistor circuit 11, N-channel transistor 12 has a drain (current electrode) connected to node N1, a gate (control electrode) connected to node N2, and a source (current electrode) connected to a power supply voltage terminal labeled “V_{SS}”. N-channel transistor 14 has a drain connected to node N2 and to the gate of transistor 12, a gate connected to node N1 and to the drain of transistor 12, and a source connected to the source of transistor 12.

In resonator circuit 15 of the described embodiment, varactors 16 and 18 are conventional metal-oxide semiconductor (MOS) varactors and are connected together in a “face-to-face” arrangement. Varactor (variable capacitor) 16 has a first electrode connected to node N1, and a second electrode connected to receive a tuning voltage labeled “V_{TUNE}”. Varactor 18 has a first electrode connected to node N2, and a second electrode connected to the second electrode of varactor 16. Inductor 20 has a first terminal connected to node N1, and a second terminal connected to a power supply voltage terminal labeled “V_{DD}”. In the described embodiment, power supply voltage terminal V_{DD} is coupled to a positive power supply voltage and V_{SS} is coupled to ground. Inductor 22 has a first terminal connected to node N2, and a second terminal connected to the second terminal of inductor 20. In accordance with one embodiment, inductors 20 and 22 each have inductance values of about 100 picohenries and varactors 16 and 18 each have a capacitance of about 40 femtofarads to about 100 femtofarads. Tuning voltage V_{TUNE} may be in a range of about −1.5 volts to 3.5 volts with V_{DD} about 1 volt. These values for inductance, capacitance, and control voltage provide a tuning range of about 36 gigahertz to about 46 gigahertz. In another embodiment, these valves for capacitance, inductance, voltage, and tuning range may be different.

The frequency of oscillating signals Vₒ₋ and Vₒ₊ is controlled by a difference in voltage between power supply voltage V_{DD} and tuning voltage V_{TUNE} by varying the capacitance of varactors 16 and 18. Transistors 12 and 14 facilitate oscillation by alternately becoming conductive and non-conductive as the voltage levels of oscillating signals Vₒ₋ and Vₒ₊ increase and decrease. In addition to generating the oscillating signal, VCO circuit 10 will also generate noise. The noise can be modulated up to the operating frequency and harmonics of the operating frequency. The noise can also be a function of the device bias and drain currents that will vary based on operating conditions. A large percentage of the noise translates into VCO phase noise. To reduce the phase noise, the illustrated embodiment provides a quarter wave impedance transformer connected to each of nodes N1 and N2. In one embodiment, the impedance transformers are implemented using transmission line stubs 24 and 26 of a length substantially equal to, or comparable to, a quarter wavelength (λ/4) at a second harmonic and are connected to nodes N1 and N2 at one end and are open at the other end. The transmission line stubs appear as a short circuit, or low impedance, to a second harmonic of the oscillating signal, thus removing, or filtering, the second harmonic. Removing the second harmonic removes a significant portion of the phase noise. However, the transmission line stubs 24 and 26 in the embodiment of FIG. 1 act as parasitic capacitance at the operating frequency of signals Vₒ₋ and Vₒ₊ and may degrade the frequency tuning range of the VCO circuit.

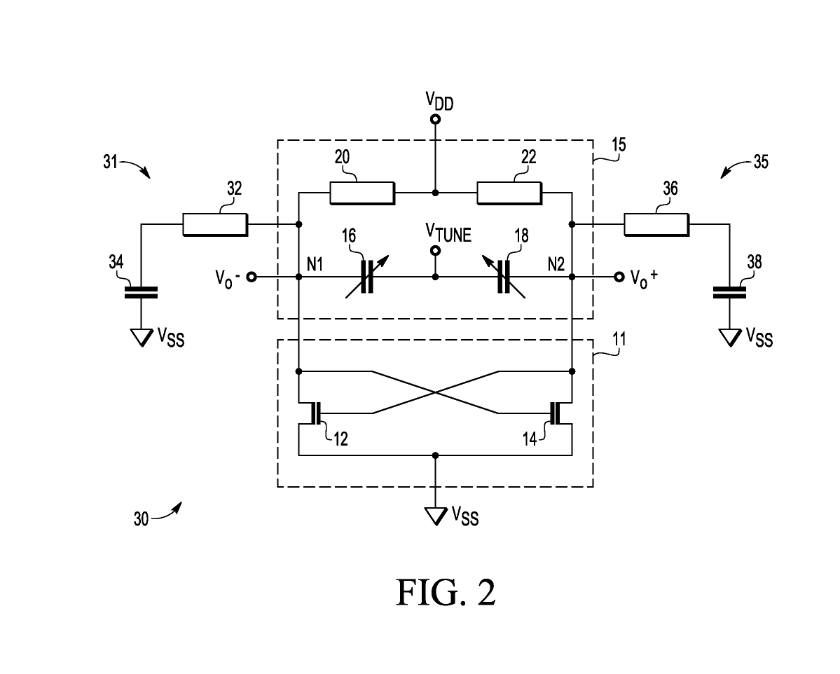

FIG. 2 illustrates, in schematic diagram form, VCO circuit 30 in accordance with another embodiment. VCO circuit 30 includes transistor circuit 11 and resonator circuit 15 connected together as described above for FIG. 1. Transistor circuit 11 and resonator circuit 15 work together to generate a differential oscillating signal Vₒ₋ and Vₒ₊ at nodes N1 and N2, respectively. As discussed above regarding the embodiment of FIG. 1, transistor circuit 11 includes N-channel transistors 12 and 14. Resonator circuit 15 includes variable capacitors (varactors) 16 and 18 and inductors 20 and 22 connected together to form an LC tank circuit. Half wave (λ/2) AC (alternating current) shorted stubs 31 and 35 each comprise a transmission line stub 32 and 36 having a length substantially equal to, or comparable to, a half wavelength at a second harmonic of the oscillating signal, and are each in series with a capacitive element. For example, AC shorted stub 31 includes transmission line 32 connected in series with capacitor 34 between node N1 and ground. Likewise, AC shorted stub 35 includes transmission line 36 connected in series with capacitor 38 between node N2 and ground. Transmission line 32 has a first end connected to node N1, and a second end. Capacitor 34 has a first electrode connected to the second end of transmission line 32, and a second electrode connected to V_{SS}. Power supply voltage terminal V_{SS} is connected to ground. Transmission line 36 has a first end connected to node N2, and a second end. Capacitor 38 has a first electrode connected to the second end of transmission line 36, and a second electrode connected to V_{SS}. Capacitors 34 and 38 are sized to provide a shorted input impedance at a fundamental frequency and above for oscillating signals Vₒ₋ and Vₒ₊. Half wave AC shorted stubs 31 and 35 are for removing a second harmonic from the oscillating signals and function as impedance transformers at a fundamental frequency, thus reflecting an impedance seen at a starting end (nodes N1 and N2) to the second end (ground). Therefore, capacitors 34 and 38 have to be relatively large. Half wave AC shorted stubs 31 and 35 have minimal impact on the tuning range of VCO circuit 30.

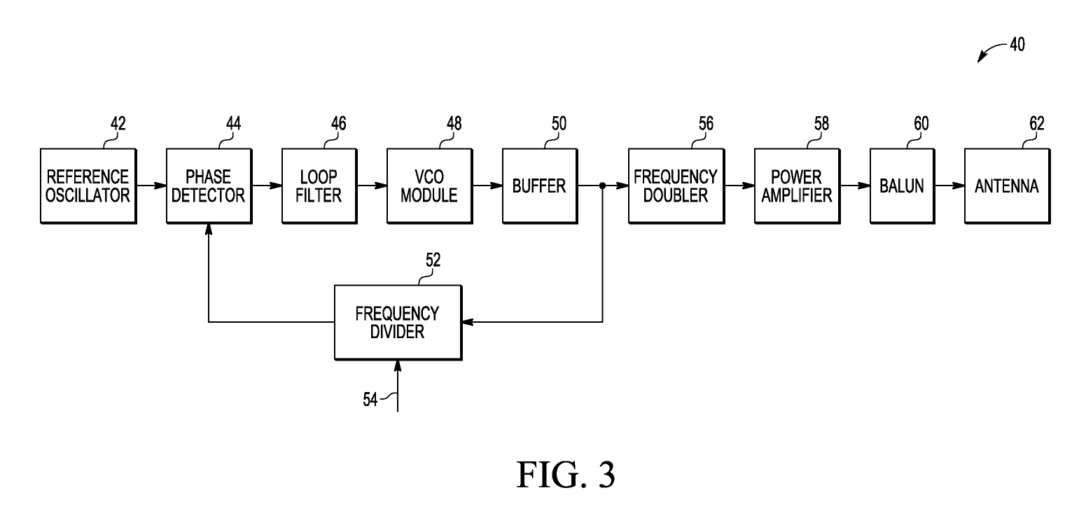

FIG. 3 illustrates, in block diagram form, a transmitter 40 that can be implemented using the VCO circuits of FIG. 1 or FIG. 2. Transmitter 40 includes reference oscillator 42, phase detector 44, loop filter 46, VCO module 48, buffer 50, frequency divider 52, frequency doubler 56, power amplifier 58, balun 60, and antenna 62. In the illustrated embodiment, reference oscillator 42, phase detector 44, loop filter 46, VCO module 48, buffer 50, and frequency divider 52 are configured as a phase-locked loop (PLL) that produces a frequency modulated oscillating signal having a desired oscillation frequency based on an input signal provided at an input 54 of the transmitter 40. In accordance with one or more embodiments, transmitter 40 is configured for automotive radar applications, wherein VCO module 48 is configured for oscillation frequencies within the range of about 38 GHz to about 41 GHz and the frequency modulated signals transmitted by antenna 62 have a frequency in the range of about 76 GHz to about 82 GHz. VCO module 48 can be implemented using one of either VCO circuit 10 (FIG. 1) or VCO circuit 30 (FIG. 2). It should be understood that FIG. 3 illustrates a simplified representation of a transmitter for purposes of explanation and ease of description, and FIG. 3 is not intended to limit the application or scope of the subject matter described herein in any way.

Reference oscillator 42 is an oscillator that generates a reference signal having a fixed reference frequency, such as, for example, a crystal oscillator. Phase detector 44 is coupled to reference oscillator 42 and frequency divider 52. Phase detector 44 compares the reference signal from the reference oscillator to the feedback signal from frequency divider 52 and generates an error signal based on the difference between the frequencies and/or phases of the feedback signal and the reference signal. In accordance with one embodiment, the error signal from phase detector 44 comprises an “up” or “down” pulse that produces a corresponding increase or decrease in a reference voltage differential provided to VCO module 48 that is proportional to the duration of the pulse. Loop filter 46 comprises an analog filter that filters the error signal from phase detector 44 to obtain a reference voltage differential which varies based on differences (e.g., in frequency and/or phase) between the reference signal and the feedback signal until the feedback signal is in phase-lock with or otherwise matches the reference signal. It will be appreciated that loop filter 46 also provides a dominant pole for the PLL, thereby ensuring stability for the PLL. Buffer 50 is coupled to the output of VCO module 48 and prevents the resulting load from the frequency divider 52 and/or frequency doubler 56 from undesirably impacting the oscillation frequency of VCO module 48. Frequency divider 52 is coupled between the output of VCO module 48 (via the buffer 50) and the input to phase detector 44, and the frequency divider 52 is configured to generate or otherwise provide the feedback signal at a frequency that is equal to a fraction of the oscillation frequency of the oscillating signal(s) from VCO module 48, wherein the fractional amount is determined based on the input signal provided at the input 54. In one embodiment, frequency divider 52 is configured to support or otherwise implement frequency modulated continuous wave signals generated by the PLL that are representative of the input signal received at input 54. In this regard, although not illustrated in FIG. 3, in practice, frequency divider 52 may include modulators, ramp generators, and other components suitably configured to support frequency modulation, as will be appreciated in the art.

VCO module 48 is implemented using VCO module 10 or VCO module 30 as described above in FIG. 1 or FIG. 2. The reference voltage differential from loop filter 46 is provided as control voltage V_{TUNE} and to control the capacitance of varactors 16 and 18, and thereby, the oscillation frequency of the differential oscillating signals at nodes N1 and N2, which are representative of frequency modulated signals to be transmitted by transmitter 40.

It should be noted that in other embodiments, VCO module 48 may be utilized in a non-differential manner for transmitter 40. In the illustrated embodiment, the output of VCO module 48 (e.g., nodes N1 and N2) is coupled to the frequency doubler 56 (via buffer 50), which doubles the frequency of the differential oscillating signals received from nodes N1 and N2. The output of frequency doubler 56 is provided to power amplifier 58, which amplifies the differential oscillating signals. The output of power amplifier 58 is provided to the input of balun 60, which is configured to convert the amplified differential oscillating signal to a single-ended oscillating signal with the same oscillating frequency. In one embodiment, antenna 62 is realized as a conductive element that is coupled to the output of balun 60 and configured to generate or otherwise produce electromagnetic waves at a frequency corresponding to the frequency of the single-ended oscillating signal received from balun 60. In this manner, antenna 62 transmits or otherwise emits an electromagnetic signal having a frequency that is influenced by the oscillating frequency of the oscillating signals provided by VCO module 48, which in this example, corresponds to twice the oscillating frequency of VCO module 48 by virtue of frequency doubler 56. For example, if VCO module 48 is producing oscillating signals with an oscillation frequency of 39 GHz, antenna 62 transmits frequency modulated electromagnetic signals having a frequency of 78 GHz.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, skilled artisans appreciated that conductivity types and polarities of potentials may be reversed.

Those skilled in the art will recognize that boundaries between the functionality of the above described operations merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. An oscillator circuit for generating an oscillating signal, the oscillator circuit comprising:
a transistor circuit coupled to a first node and a second node of the oscillator circuit, the transistor circuit for facilitating oscillation of the oscillating signal;
a resonator circuit coupled to the first node and the second node, the resonator circuit comprising an inductance and a capacitance;
a first transmission line open stub having a first length substantially equal to a quarter wavelength of a second harmonic of the oscillating signal, the first transmission line open stub coupled to the first node; and
a second transmission line open stub having a second length substantially equal to the quarter wavelength of the second harmonic of the oscillating signal, the second transmission line coupled to the second node,
wherein the first and second transmission line open stubs are for removing a second harmonic from the oscillating signal.

2. The oscillator circuit of claim 1, wherein the transistor circuit comprises:
a first transistor having a first current electrode coupled to the first node, a second current electrode coupled to a first power supply voltage terminal, and a control electrode coupled to the second node; and
a second transistor having a first current electrode coupled to the second node and to the control electrode of the first transistor, a second current electrode coupled to the first power supply voltage terminal, and a control electrode coupled to the first node.

3. The oscillator circuit of claim 2, wherein the inductance and the capacitance further comprises:
a first inductive element having a first terminal coupled to a second power supply voltage terminal, and a second terminal coupled to the first node;
a second inductive element having a first terminal coupled to a second power supply voltage terminal, and a second terminal coupled to the second node;
a first capacitive element having a first electrode coupled to the first node, and a second electrode for receiving a tuning voltage; and
a second capacitive element having a first electrode coupled to the second node, and a second electrode coupled to the second electrode of the first capacitive element for receiving the tuning voltage.

4. The oscillator circuit of claim 3, wherein the first power supply voltage terminal is coupled to ground and the second power supply voltage terminal is coupled to receive a positive power supply voltage.

5. The oscillator circuit of claim 3, wherein the first and second inductive elements each comprise transmission line segments.

6. The oscillator circuit of claim 3, wherein the first capacitive element and the second capacitive element each comprise a varactor.

7. The oscillator circuit of claim 6, wherein the varactor is characterized as being a metal-oxide semiconductor (MOS) varactor.

8. The oscillator circuit of claim 1, wherein the transistor circuit comprises a pair of cross-coupled N-channel transistors.

9. The oscillator circuit of claim 1, wherein the oscillator circuit is characterized as being a voltage controlled oscillator.

10. The oscillator circuit of claim 9, wherein the voltage controlled oscillator is part of a radar frequency transmitter.

11. An oscillator circuit for providing an oscillating signal, the oscillator circuit comprising:
a transistor circuit coupled to a first node and a second node of the oscillator circuit;
a resonator circuit coupled to the first node and the second node;
a first half wave AC (alternating current) shorted stub coupled to the first node; and
a second half wave AC shorted stub coupled to the second node;
wherein the first and second half wave AC shorted stubs each comprise a transmission line in series with a capacitive element, wherein the transmission line has a length substantially equal to a half wavelength of a second harmonic of the oscillating signal, wherein the capacitive element is sized to provide a shorted input impedance at a fundamental frequency and above, and wherein the first and second half wave AC shorted stubs are for removing a second harmonic from the oscillating signal.

12. The oscillator circuit of claim 11, wherein the transistor circuit comprises:
a first transistor having a first current electrode coupled to the first node, a second current electrode coupled to a first power supply voltage terminal, and a control electrode coupled to the second node; and
a second transistor having a first current electrode coupled to the second node and to the control electrode of the first transistor, a second current electrode coupled to the first power supply voltage terminal, and a control electrode coupled to the first node.

13. The oscillator circuit of claim 11, wherein the resonator circuit further comprises:
a first inductive element having a first terminal coupled to a second power supply voltage terminal, and a second terminal coupled to the first node;
a second inductive element having a first terminal coupled to the second power supply voltage terminal, and a second terminal coupled to the second node;
a first capacitive element having a first electrode coupled to the first node, and a second electrode for receiving a tuning voltage; and
a second capacitive element having a first electrode coupled to the second node, and a second electrode coupled to the second electrode of the first capacitive element for receiving the tuning voltage.

14. The oscillator circuit of claim 13, wherein the first power supply voltage terminal is coupled to ground and the second power supply voltage terminal is coupled to receive a positive power supply voltage.

15. The oscillator circuit of claim 13, wherein the first and second inductive elements each comprise transmission line segments.

16. The oscillator circuit of claim 13, wherein the first capacitive element and the second capacitive element each comprise a varactor.

17. The oscillator circuit of claim 16, wherein the varactor is implemented as a metal-oxide semiconductor (MOS) varactor.

18. The oscillator circuit of claim 11, wherein the transistor circuit comprises a pair of cross-coupled N-channel transistors.

19. The oscillator circuit of claim 11, wherein the oscillator circuit is characterized as being a voltage controlled oscillator.

20. The oscillator circuit of claim 19, wherein the voltage controlled oscillator is part of a radar frequency transmitter.
